(19) United States
(12) Patent Application Publication
(10) Pub. No.: US 2024/0076977 A1
(43) Pub. Date: Mar. 7, 2024

(54) PREDICTING HYDROCARBON SHOW INDICATORS AHEAD OF DRILLING BIT

(71) Applicant: Saudi Arabian Oil Company, Dhahran (SA)

(72) Inventors: Yasser S. Ghamdi, Dhahran (SA); Rakan Alkheliwi, Dhahran (SA)

(21) Appl. No.: 17/901,681

(22) Filed: Sep. 1, 2022

(51) Int. Cl. E21B 49/00; E21B 45/00; E21B 47/04; E21B 47/09

(52) U.S. Cl. CPC E21B 49/005; E21B 45/00; E21B 47/04; E21B 47/09; E21B 2200/22

(57) ABSTRACT

Systems and methods include techniques for predicting hydrocarbon show indicators classifying a presence of hydrocarbons at a pre-determined distance ahead of a drilling bit. Input data is received that identifies, for different depths of a well that is being drilled, a drill bit location, a depth, a weight on bit, rotations per minute, a rate of penetration, lagged lithology percentages, and real-time mud gas logs. Data cleaning is performed on the input data using an isolation forest algorithm to remove outliers. A sequence of attributes for the well being drilled is identified from the input data, where the sequence of attributes includes the input data measured at a sequence of depths in the well. Hydrocarbon show indicators classifying a presence of hydrocarbons at a pre-determined distance ahead of a drilling bit are predicted in real time using machine learning on the sequence of attributes received while drilling the well.

### TECHNICAL FIELD

The present disclosure applies to drilling wells, such as oil wells.

### BACKGROUND

In the daily operations of drilling an oil well, for example, decisions can be made at the end of each day whether or not to abandon a well if hydrocarbons are not expected. This can be useful, for example, for making a daily decision on whether or not to continue drilling an exploration well.

### SUMMARY

The present disclosure describes techniques that can be used to generate a model for predicting hydrocarbon show indicators, e.g., hydrocarbon wetness. Using machine learning techniques, indicators such as hydrocarbon wetness can be used to classify the existence (e.g., presence or absence) of productive oil, e.g., 1000 feet ahead, in a downhole direction of a drilling bit. In some implementations, a computer-implemented method includes the following. Input data is received that identifies, for different depths of a well that is being drilled, a drill bit location, a depth, a weight on bit, rotations per minute, a rate of penetration, lagged lithology percentages, and real-time mud gas logs. Data cleaning is performed on the input data using an isolation forest algorithm to remove outliers. A sequence of attributes for the well being drilled is identified from the input data, where the sequence of attributes includes the input data measured at a sequence of depths in the well. Hydrocarbon show indicators classifying a presence of hydrocarbons at a pre-determined distance ahead of a drilling bit are predicted in real time using machine learning on the sequence of attributes received while drilling the well.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method, the instructions stored on the non-transitory, computer-readable medium.

The subject matter described in this specification can be implemented in particular implementations, so as to realize one or more of the following advantages. Hydrocarbon shows can be predicted 1000 feet ahead, in a downhole direction of drilling bit, reducing costs, e.g., by allowing geologists to abandon a well if hydrocarbons are not expected. This can be useful, for example, in daily operations in which a decision is made on a daily basis whether or not to continue drilling an exploration well. The early decisions based on the existence (e.g., presence or absence) of hydrocarbons 1000 feet ahead of the drilling bit can be made based on 100 feet of sequence data integrated to a wellsite hub. The techniques of the present disclosure can focus, at least in part, on forecasting hydrocarbon shows through the use of machine learning capabilities.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### DESCRIPTION OF DRAWINGS

FIG. 1 shows a table listing example comparisons of parameters, accuracies, and results of different isolation forest algorithms, according to some implementations of the present disclosure.

FIG. 2 shows a listing of code and parameters for executing a random forest algorithm, according to some implementations of the present disclosure.

FIG. 3 is a flowchart of an example of a workflow for predicting a hydrocarbon show ahead of a drilling bit, according to some implementations of the present disclosure.

FIG. 4 is a flowchart of an example of a method for predicting, using machine learning on the sequence of attributes, hydrocarbon show indicators classifying an existence of productive oil within a pre-determined distance ahead of a drilling bit, according to some implementations of the present disclosure.

FIG. 5 is a block diagram illustrating an example computer system used to provide computational functionalities associated with described algorithms, methods, functions, processes, flows, and procedures as described in the present disclosure, according to some implementations of the present disclosure.

Like reference numbers and designations in the various drawings indicate like elements.

### DETAILED DESCRIPTION

The following detailed description describes techniques for generating a model for predicting hydrocarbon show indicators, e.g., hydrocarbon wetness. Using machine learning techniques, indicators such as hydrocarbon wetness can be used to classify the existence (e.g., presence or absence) of productive oil, e.g., 1000 feet ahead, in a downhole direction of a drilling bit. Other techniques other than hydrocarbon show can be used to determine hydrocarbon wetness. Various modifications, alterations, and permutations of the disclosed implementations can be made and will be readily apparent to those of ordinary skill in the art, and the general principles defined may be applied to other implementations and applications, without departing from the scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

The present disclosure describes the use of a machine learning model for predicting hydrocarbon prospects ahead of a drilling bit, such as while drilling an oil well. For example, the technology relates to predicting hydrocarbon show indicators, namely, hydrocarbon wetness, to classify the existence of productive oil at a distance (e.g., 1000 feet) ahead, in a downhole direction of a drilling bit, using machine learning methods. Input data related to drilling bit location, depth, weight on bit, RPM, ROP, lagged lithology percentages, and real-time mud gas logs can be gathered. Balanced random forest algorithms can be implemented using the input features. Then, a Haworth Wetness Formula can be used on mud gases logs to indicate if oil is productive. If the formula yields a value within a specified range (e.g., 0.5 to 40%), then that indicates productive hydrocarbons. Sequences of 100 feet of these attributes are taken to predict hydrocarbon shows within the pre-determined distance (e.g., 1000 feet) of the drilling bit. Attributes can include, for example, drill time, gas readings, weight on bit, rotations per minute, depth, and latitude/longitude.

A prediction can be based on the execution of a balanced random forest algorithm that considers location, depth, weight-on-bit, rotations-per-minute, rate-of-penetration, lagged lithology percentages (e.g., values from 1 to 100), and real-time mud gas logs as inputs to the algorithm. Determining that hydrocarbon prospects likely exist ahead of a drilling bit can be attained by running a Haworth Wetness Formula that indicates if productive oil is present on mud gases logs. A value between 0.5 and 40%, for example, indicates the presence of productive hydrocarbons. A sequence of 100 of such attributes (e.g., drill time, gas readings, weight on bit, rotation per minute, depth, and latitude/longitude) can be used to predict hydrocarbon shows 1000 feet ahead, in a downhole direction of the drilling bit. When a depth of 1000 is reached in a well, the information that is typically shown to a geologist in real-time includes lithology percentages at around 970 feet. This is the reason for the so-called “lagged” aspect to overcome the time delay issue of reading data in real-time. Real-time mud gases are values of mud gases at a depth of 1000 when the well is drilled at a depth of 1000. Values of real-time mud gases can range between 0-1000000 parts per million (ppm).

In some implementations, it is possible to predict the presence at different depths other than 1000 feet (e.g., 250 feet, 500 feet, 750 feet, or 1250 feet). The choice of using 1000 feet can be based on the ability to create more values on which to base more accurate predictions at that depth. In general, the use of lower depths can result in more accurate model results. The depth of 1000 feet can be determined using a machine learning model, e.g., a random forest.

Execution of the Haworth Wetness Formula (HWF) can be based on a mix of 100 feet of data, where the wetness ratio Wₕ can be given by:

$${W}_{h} = \frac{{C}_{2} + {C}_{3} + i {C}_{4} + n {C}_{4} + {C}_{5}}{{C}_{1} + {C}_{2} + … + {C}_{5}} \cdot 100 \qquad ( 1 )$$

where C₁=methane, C₂=ethane, C₃=propane, C₄₊=butanes and heavier, C₅₊=pentanes and heavier, and Cₕ=character ratio. The HWF can be used as a preprocessed input to mud gases to create the shows labels.

Techniques used in the present disclosure can use the following types of concepts and functions.

### Data Wrangling

Data wrangling can be used as a data cleaning mechanism in the isolation forest to remove outliers. For example, in data cleaning, ROP values below 0 and above 200 can be removed as not being reasonable. For lithology, multiple variables can be pivoted with percentages used as values. For gas, values less than 0 can be removed. An isolation forest algorithm can determine outliers, for example, using:

$$( x , n ) = {2}^{- \frac{E ( h ( x ) )}{c ( n )}} \qquad ( 2 )$$

where x is an observation, n is a testing data set size, E (h(x)) is an advantage value of h(x), h(x) is harmonic number of x, and c(n) is the average of h(x) given n in order to normalize the value. A score at a pre-determined threshold (e.g., close to 1.0) can indicate that an outlier is to be removed.

### Isolation Forest

The step of removing outliers is done in order to improve the accuracy of the model. The Isolation Forest is an anomaly detection algorithm that works by isolating values that deviate too much from the rest of the data.

### Standardization Using Standard Scaler and Zscore Normalization.

Standard scalers can be used on values across columns, and Zscore can be used on values across rows, in order to make training smoother. Standard scalers can be used to standardize data to be between 0 and 1 in a normally distributed shape. Zscore only provides normalization, without being between 0 and 1. This is a step taken in machine learning algorithms to make it easier for the model to find the best answer. When the random forest algorithm is run, balanced class weight is used in order to force the model to score all 0s or all 1s. Instead, the algorithm can be programmed so that, for example, the weight of 0 is 0.9 while the weight of 1 is 0.1. This is done so that the algorithm can find as many 0s even though 0s may be few in the dataset.

### Sequence Generation Every 100 Feet

Sequences of attributes were generated, with every 10 rows (e.g., 100 feet per row) representing a sequence. The sequences of attributes were built with a rolling window meaning that if depth values are 10, 20, or 30 feet, for example, the next window show 20, 30, or 40 feet.

Modeling Using Random Forest Classifier with Balanced Class Weight

Performance can be measured, for example, by averaging: accuracy at 90%; ROC-AUC at 90%; precision, recall, and an F1 score around 90%.

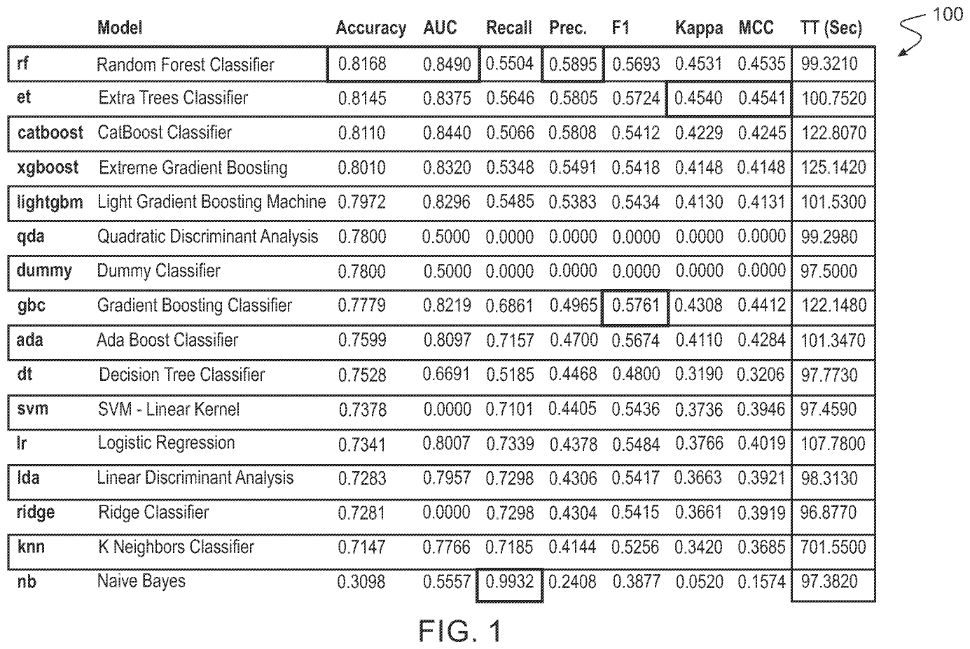

The results of comparing the random forest algorithm to other algorithm are summarized in FIG. 1. Experimentation was used to determine that, among the algorithms tested, the random forest algorithm outperformed the other algorithms. Then, the experiments were repeated with the random forest algorithm with a balanced class.

FIG. 1 shows a table 100 listing example comparisons of parameters, accuracies, and results of random forest algorithms, according to some implementations of the present disclosure.

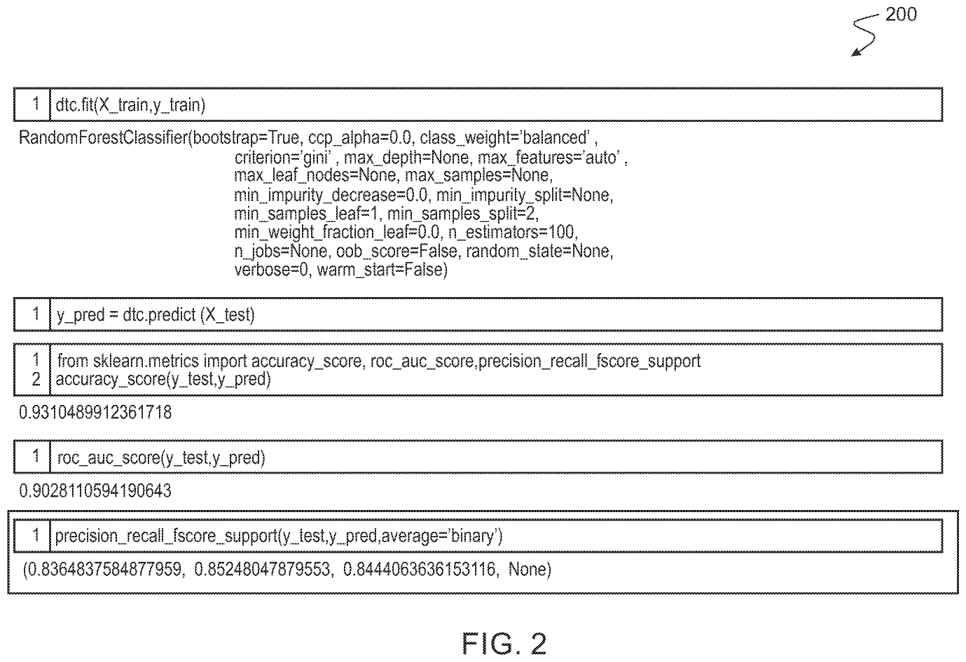

FIG. 2 shows a listing 200 of codes and parameters for executing a random forest algorithm, according to some implementations of the present disclosure.

### Modeling

The data can be modeled using open source tools and doing basic comparisons. The results, upon experimentation, can show that random forest is the best algorithm for the techniques of the present disclosure. The training can be repeated again using open source tools with Random Forest set with balanced class weights. Random Forest is an ensemble algorithm that works by building multiple decision trees that vote on the class of the data. During experimentation, deep learning methods such as LSTM, RNN, and transformers were used. However, it was determined that these algorithms have the disadvantage of lower performance due to a lack of a large data set with which to feed the network.

The output is a class that indicates whether there is show or no show. The process can use a machine learning algorithm that captures relations between input features and classes based on either gini or entropy. As an example, the following formula can be used:

Gini=1−Σₗ₌₁^{C}(pᵢ)² (3)

where Gini is a probability of classifying a data point incorrectly, C is number of classes in this example 2, and Pᵢ is a ratio of class at the ith node.

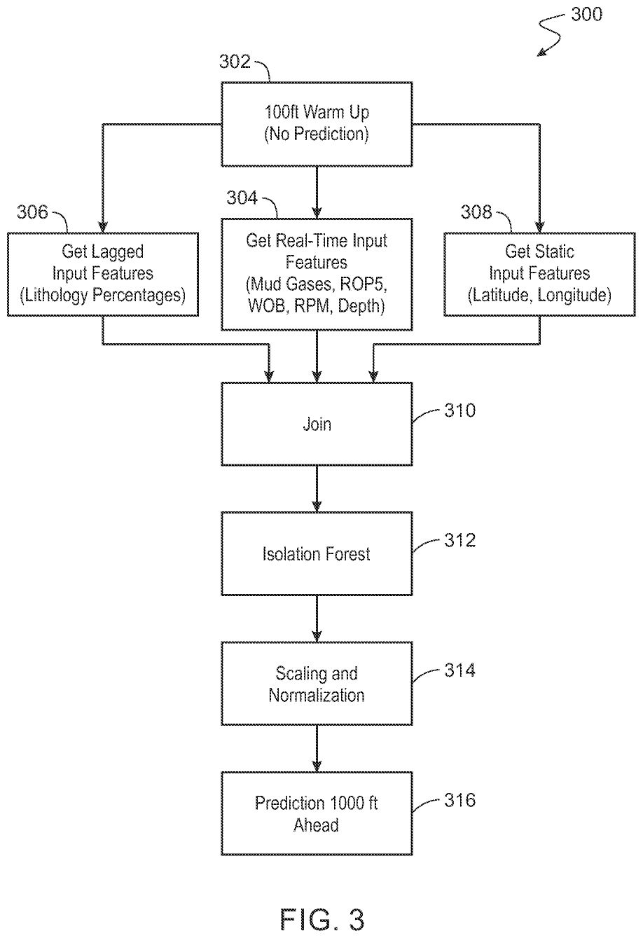

FIG. 3 is a flowchart of an example of a workflow 300 for predicting a hydrocarbon show ahead of a drilling bit, according to some implementations of the present disclosure.

At 302, a 100-foot warm-up with no prediction is performed in order to skip the first 100 feet of the well since no prediction can be made. At 304, real-time input features are obtained, including mud gases, ROPS, WOB, RPM, and depth. At 306, lagged input features, including lithology and percentages, and obtained At 308, static input features, including latitude and longitude, and obtained. At 310, the data is combined (e.g., tables are joined). At 312, (e.g., a forest algorithm (e.g., isolation forest) is executed. At 314, the data is scaled and normalized, e.g., standard scalers and normalizers can be used to smoothen the data. At 316, a prediction is made whether hydrocarbon shows occur within 1000 feet ahead, in a downhole direction of the drilling bit. For example, one to five models can be used based on a distance from one of five regions near the well. A notification message generated by the software can state a prediction 1000 feet ahead of the drilling bit. The notification can be a popup message, an email, or a Chabot, for example.

Techniques of the present disclosure were tested on sequences for around 400 exploration wells in multiple locations. During the testing, the Random Forest algorithm was selected as the algorithm that performed best.

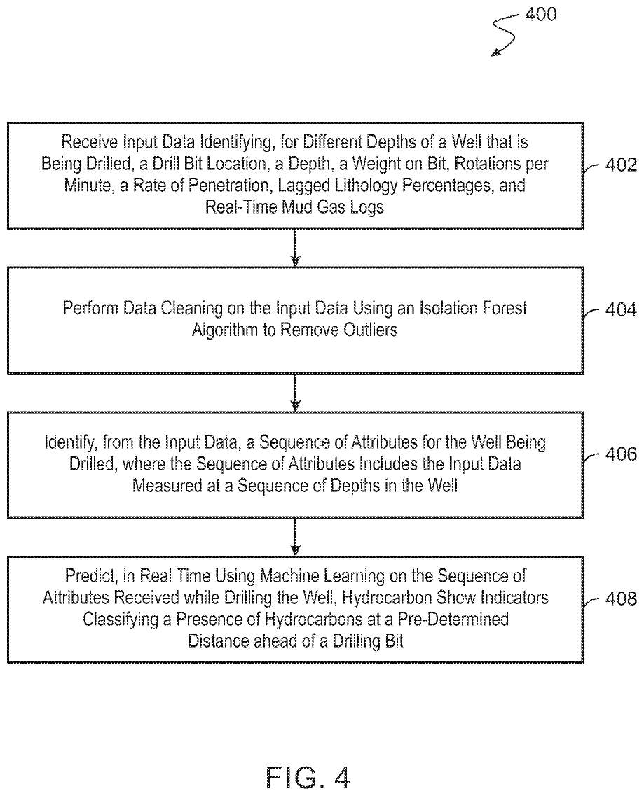

FIG. 4 is a flowchart of an example of a method 400 for predicting, using machine learning on the sequence of attributes, hydrocarbon show indicators classifying an existence of productive oil within a pre-determined distance ahead of a drilling bit, according to some implementations of the present disclosure. For clarity of presentation, the description that follows generally describes method 400 in the context of the other figures in this description. However, it will be understood that method 400 can be performed, for example, by any suitable system, environment, software, and hardware, or a combination of systems, environments, software, and hardware, as appropriate. In some implementations, various steps of method 400 can be run in parallel, in combination, in loops, or in any order.

At 402, input data is received that identifies, for different depths of a well that is being drilled, a drill bit location, a depth, a weight on bit, rotations per minute, a rate of penetration, lagged lithology percentages, and real-time mud gas logs. In some implementations, the input data can be scaled and normalized. From 402, method 400 proceeds to 404.

At 404, data cleaning is performed on the input data using an isolation forest algorithm to remove outliers. For example, balanced random forest algorithms can be implemented using the input features in order to remove outliers, e.g., data points that are outside of a predetermined range of values. From 404, method 400 proceeds to 406.

At 406, a sequence of attributes for the well being drilled is identified from the input data, where the sequence of attributes includes the input data measured at a sequence of depths in the well. As an example, the sequence of attributes can include attributes for 100 feet of drilling. From 406, method 400 proceeds to 408.

At 408, hydrocarbon show indicators classifying a presence of hydrocarbons at a pre-determined distance ahead of a drilling bit are predicted in real time using machine learning on the sequence of attributes received while drilling the well. As an example, predicting the hydrocarbon show indicators can include using a Haworth Wetness formula to determine, using mud gases logs, if oil is productive ahead of the drilling bit. Predicting the hydrocarbon show indicators includes determining that Haworth Wetness formula yields a value within a specified range of 0.5 to 40%, indicating productive hydrocarbons. Predicting hydrocarbon show indicators classifying the presence of hydrocarbons can include predicting a presence or absence of productive amounts of one or more of oil and natural gas. The hydrocarbon show indicators can include hydrocarbon wetness, for example. The pre-determined distance can be 1000 feet ahead, in a downhole direction of the drilling bit. After 408, method 400 can stop.

In some implementations, method 400 further includes performing real world tasks based on the predicting. For example, directional drilling can be automatically performed and the drill bit can be steered to regions predicted to have productive oil. In another example, a decision can be made whether to continue drilling or stop drilling at a particular point, e.g., when the likelihood of productive oil drops below a pre-determined threshold percentage.

In some implementations, in addition to (or in combination with) any previously-described features, techniques of the present disclosure can include the following. Outputs of the techniques of the present disclosure can be performed before, during, or in combination with wellbore operations, such as to provide inputs to change the settings or parameters of equipment used for drilling. Examples of wellbore operations include forming/drilling a wellbore, hydraulic fracturing, and producing through the wellbore, to name a few. The wellbore operations can be triggered or controlled, for example, by outputs of the methods of the present disclosure. In some implementations, customized user interfaces can present intermediate or final results of the above described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or “app”), or at a central processing facility. The presented information can include suggestions, such as suggested changes in parameters or processing inputs, that the user can select to implement improvements in a production environment, such as in the exploration, production, and/or testing of petrochemical processes or facilities. For example, the suggestions can include parameters that, when selected by the user, can cause a change to, or an improvement in, drilling parameters (including drilling bit speed and direction) or overall production of a gas or oil well. The suggestions, when implemented by the user, can improve the speed and accuracy of calculations, streamline processes, improve models, and solve problems related to efficiency, performance, safety, reliability, costs, downtime, and the need for human interaction. In some implementations, the suggestions can be implemented in real-time, such as to provide an immediate or near-immediate change in operations or in a model. The term real-time can correspond, for example, to events that occur within a specified period of time, such as within one minute or within one second. Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

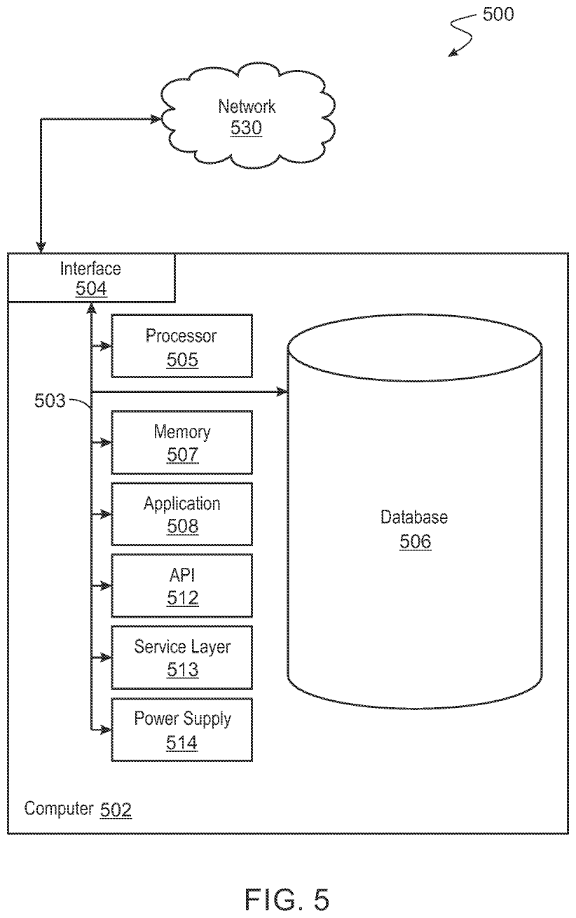

FIG. 5 is a block diagram of an example computer system 500 used to provide computational functionalities associated with described algorithms, methods, functions, processes, flows, and procedures described in the present disclosure, according to some implementations of the present disclosure. The illustrated computer 502 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 502 can include input devices such as keypads, keyboards, and touch screens that can accept user information. Also, the computer 502 can include output devices that can convey information associated with the operation of the computer 502. The information can include digital data, visual data, audio information, or a combination of information. The information can be presented in a graphical user interface (UI) (or GUI).

The computer 502 can serve in a role as a client, a network component, a server, a database, a persistency, or components of a computer system for performing the subject matter described in the present disclosure. The illustrated computer 502 is communicably coupled with a network 530. In some implementations, one or more components of the computer 502 can be configured to operate within different environments, including cloud-computing-based environments, local environments, global environments, and combinations of environments.

At a top level, the computer 502 is an electronic computing device operable to receive, transmit, process, store, and manage data and information associated with the described subject matter. According to some implementations, the computer 502 can also include, or be communicably coupled with, an application server, an email server, a web server, a caching server, a streaming data server, or a combination of servers.

The computer 502 can receive requests over network 530 from a client application (for example, executing on another computer 502). The computer 502 can respond to the received requests by processing the received requests using software applications. Requests can also be sent to the computer 502 from internal users (for example, from a command console), external (or third) parties, automated applications, entities, individuals, systems, and computers.

Each of the components of the computer 502 can communicate using a system bus 503. In some implementations, any or all of the components of the computer 502, including hardware or software components, can interface with each other or the interface 504 (or a combination of both) over the system bus 503. Interfaces can use an application programming interface (API) 512, a service layer 513, or a combination of the API 512 and service layer 513. The API 512 can include specifications for routines, data structures, and object classes. The API 512 can be either computer-language independent or dependent. The API 512 can refer to a complete interface, a single function, or a set of APIs.

The service layer 513 can provide software services to the computer 502 and other components (whether illustrated or not) that are communicably coupled to the computer 502. The functionality of the computer 502 can be accessible for all service consumers using this service layer. Software services, such as those provided by the service layer 513, can provide reusable, defined functionalities through a defined interface. For example, the interface can be software written in JAVA, C++, or a language providing data in extensible markup language (XML) format. While illustrated as an integrated component of the computer 502, in alternative implementations, the API 512 or the service layer 513 can be stand-alone components in relation to other components of the computer 502 and other components communicably coupled to the computer 502. Moreover, any or all parts of the API 512 or the service layer 513 can be implemented as child or sub-modules of another software module, enterprise application, or hardware module without departing from the scope of the present disclosure.

The computer 502 includes an interface 504. Although illustrated as a single interface 504 in FIG. 5, two or more interfaces 504 can be used according to particular needs, desires, or particular implementations of the computer 502 and the described functionality. The interface 504 can be used by the computer 502 for communicating with other systems that are connected to the network 530 (whether illustrated or not) in a distributed environment. Generally, the interface 504 can include, or be implemented using, logic encoded in software or hardware (or a combination of software and hardware) operable to communicate with the network 530. More specifically, the interface 504 can include software supporting one or more communication protocols associated with communications. As such, the network 530 or the interface's hardware can be operable to communicate physical signals within and outside of the illustrated computer 502.

The computer 502 includes a processor 505. Although illustrated as a single processor 505 in FIG. 5, two or more processors 505 can be used according to particular needs, desires, or particular implementations of the computer 502 and the described functionality. Generally, the processor 505 can execute instructions and can manipulate data to perform the operations of the computer 502, including operations using algorithms, methods, functions, processes, flows, and procedures as described in the present disclosure.

The computer 502 also includes a database 506 that can hold data for the computer 502 and other components connected to the network 530 (whether illustrated or not). For example, database 506 can be an in-memory, conventional, or a database storing data consistent with the present disclosure. In some implementations, database 506 can be a combination of two or more different database types (for example, hybrid in-memory and conventional databases) according to particular needs, desires, or particular implementations of the computer 502 and the described functionality. Although illustrated as a single database 506 in FIG. 5, two or more databases (of the same, different, or combination of types) can be used according to particular needs, desires, or particular implementations of the computer 502 and the described functionality. While database 506 is illustrated as an internal component of the computer 502, in alternative implementations, database 506 can be external to the computer 502.

The computer 502 also includes a memory 507 that can hold data for the computer 502 or a combination of components connected to the network 530 (whether illustrated or not). Memory 507 can store any data consistent with the present disclosure. In some implementations, memory 507 can be a combination of two or more different types of memory (for example, a combination of semiconductor and magnetic storage) according to particular needs, desires, or particular implementations of the computer 502 and the described functionality. Although illustrated as a single memory 507 in FIG. 5, two or more memories 507 (of the same, different, or combination of types) can be used according to particular needs, desires, or particular implementations of the computer 502 and the described functionality. While memory 507 is illustrated as an internal component of the computer 502, in alternative implementations, memory 507 can be external to the computer 502.

The application 508 can be an algorithmic software engine providing functionality according to particular needs, desires, or particular implementations of the computer 502 and the described functionality. For example, application 508 can serve as one or more components, modules, or applications. Further, although illustrated as a single application 508, the application 508 can be implemented as multiple applications 508 on the computer 502. In addition, although illustrated as internal to the computer 502, in alternative implementations, the application 508 can be external to the computer 502.

The computer 502 can also include a power supply 514. The power supply 514 can include a rechargeable or non-rechargeable battery that can be configured to be either user- or non-user-replaceable. In some implementations, the power supply 514 can include power-conversion and management circuits, including recharging, standby, and power management functionalities. In some implementations, the power supply 514 can include a power plug to allow the computer 502 to be plugged into a wall socket or a power source to, for example, power the computer 502 or recharge a rechargeable battery.

There can be any number of computers 502 associated with, or external to, a computer system containing computer 502, with each computer 502 communicating over network 530. Further, the terms “client,” “user,” and other appropriate terminology can be used interchangeably, as appropriate, without departing from the scope of the present disclosure. Moreover, the present disclosure contemplates that many users can use one computer 502 and one user can use multiple computers 502.

Described implementations of the subject matter can include one or more features, alone or in combination.

For example, in a first implementation, a computer-implemented method includes the following. Input data is received that identifies, for different depths of a well that is being drilled, a drill bit location, a depth, a weight on bit, rotations per minute, a rate of penetration, lagged lithology percentages, and real-time mud gas logs. Data cleaning is performed on the input data using an isolation forest algorithm to remove outliers. A sequence of attributes for the well being drilled is identified from the input data, where the sequence of attributes includes the input data measured at a sequence of depths in the well. Hydrocarbon show indicators classifying a presence of hydrocarbons at a pre-determined distance ahead of a drilling bit are predicted in real time using machine learning on the sequence of attributes received while drilling the well.

The foregoing and other described implementations can each, optionally, include one or more of the following features:

A first feature, combinable with any of the following features, where the method further includes scaling and normalizing the input data.

A second feature, combinable with any of the previous or following features, where the hydrocarbon show indicators include hydrocarbon wetness.

A third feature, combinable with any of the previous or following features, where predicting the hydrocarbon show indicators includes using a Haworth Wetness formula to determine, using mud gases logs, if oil is productive ahead of the drilling bit.

A fourth feature, combinable with any of the previous or following features, where predicting the hydrocarbon show indicators includes determining that Haworth Wetness formula yields a value within a specified range of 0.5 to 40%, indicating productive hydrocarbons.

A fifth feature, combinable with any of the previous or following features, where the sequence of attributes includes attributes for 100 feet of drilling.

A sixth feature, combinable with any of the previous or following features, where the pre-determined distance is 1000 feet ahead, in a downhole direction of the drilling bit.

A seventh feature, combinable with any of the previous or following features, predicting hydrocarbon show indicators classifying the presence of hydrocarbons includes predicting a presence or absence of productive amounts of one or more of oil and natural gas.

In a second implementation, a non-transitory, computer-readable medium stores one or more instructions executable by a computer system to perform operations including the following. Input data is received that identifies, for different depths of a well that is being drilled, a drill bit location, a depth, a weight on bit, rotations per minute, a rate of penetration, lagged lithology percentages, and real-time mud gas logs. Data cleaning is performed on the input data using an isolation forest algorithm to remove outliers. A sequence of attributes for the well being drilled is identified from the input data, where the sequence of attributes includes the input data measured at a sequence of depths in the well. Hydrocarbon show indicators classifying a presence of hydrocarbons at a pre-determined distance ahead of a drilling bit are predicted in real time using machine learning on the sequence of attributes received while drilling the well.

The foregoing and other described implementations can each, optionally, include one or more of the following features:

A first feature, combinable with any of the following features, where the operations further include scaling and normalizing the input data.

A second feature, combinable with any of the previous or following features, where the hydrocarbon show indicators include hydrocarbon wetness.

A third feature, combinable with any of the previous or following features, where predicting the hydrocarbon show indicators includes using a Haworth Wetness formula to determine, using mud gases logs, if oil is productive ahead of the drilling bit.

A fourth feature, combinable with any of the previous or following features, where predicting the hydrocarbon show indicators includes determining that Haworth Wetness formula yields a value within a specified range of 0.5 to 40%, indicating productive hydrocarbons.

A fifth feature, combinable with any of the previous or following features, where the sequence of attributes includes attributes for 100 feet of drilling.

A sixth feature, combinable with any of the previous or following features, where the pre-determined distance is 1000 feet ahead, in a downhole direction of the drilling bit.

A seventh feature, combinable with any of the previous or following features, predicting hydrocarbon show indicators classifying the presence of hydrocarbons includes predicting a presence or absence of productive amounts of one or more of oil and natural gas.

In a third implementation, a computer-implemented system includes one or more processors and a non-transitory computer-readable storage medium coupled to the one or more processors and storing programming instructions for execution by the one or more processors. The programming instructions instruct the one or more processors to perform operations including the following. Input data is received that identifies, for different depths of a well that is being drilled, a drill bit location, a depth, a weight on bit, rotations per minute, a rate of penetration, lagged lithology percentages, and real-time mud gas logs. Data cleaning is performed on the input data using an isolation forest algorithm to remove outliers. A sequence of attributes for the well being drilled is identified from the input data, where the sequence of attributes includes the input data measured at a sequence of depths in the well. Hydrocarbon show indicators classifying a presence of hydrocarbons at a pre-determined distance ahead of a drilling bit are predicted in real time using machine learning on the sequence of attributes received while drilling the well.

The foregoing and other described implementations can each, optionally, include one or more of the following features:

A first feature, combinable with any of the following features, where the operations further include scaling and normalizing the input data.

A second feature, combinable with any of the previous or following features, where the hydrocarbon show indicators include hydrocarbon wetness.

A third feature, combinable with any of the previous or following features, where predicting the hydrocarbon show indicators includes using a Haworth Wetness formula to determine, using mud gases logs, if oil is productive ahead of the drilling bit.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or TO S.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY.

The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at the application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method, comprising:
receiving input data identifying, for different depths of a well that is being drilled, a drill bit location, a depth, a weight on bit, rotations per minute, a rate of penetration, lagged lithology percentages, and real-time mud gas logs;
performing data cleaning on the input data using an isolation forest algorithm to remove outliers;
identifying, from the input data, a sequence of attributes for the well being drilled, wherein the sequence of attributes includes the input data measured at a sequence of depths in the well; and
predicting, in real time using machine learning on the sequence of attributes received while drilling the well, hydrocarbon show indicators classifying a presence of hydrocarbons at a pre-determined distance ahead of a drilling bit.

2. The computer-implemented method of claim 1, further comprising scaling and normalizing the input data.

3. The computer-implemented method of claim 1, wherein the hydrocarbon show indicators include hydrocarbon wetness.

4. The computer-implemented method of claim 1, wherein predicting the hydrocarbon show indicators includes using a Haworth Wetness formula to determine, using mud gases logs, if oil is productive ahead of the drilling bit.

5. The computer-implemented method of claim 4, wherein predicting the hydrocarbon show indicators includes determining that Haworth Wetness formula yields a value within a specified range of 0.5 to 40%, indicating productive hydrocarbons.

6. The computer-implemented method of claim 1, wherein the sequence of attributes includes attributes for 100 feet of drilling.

7. The computer-implemented method of claim 1, wherein the pre-determined distance is 1000 feet ahead, in a downhole direction of the drilling bit.

8. The computer-implemented method of claim 1, wherein predicting hydrocarbon show indicators classifying the presence of hydrocarbons includes predicting a presence or absence of productive amounts of one or more of oil and natural gas.

9. A non-transitory, computer-readable medium storing one or more instructions executable by a computer system to perform operations comprising:
receiving input data identifying, for different depths of a well that is being drilled, a drill bit location, a depth, a weight on bit, rotations per minute, a rate of penetration, lagged lithology percentages, and real-time mud gas logs;
performing data cleaning on the input data using an isolation forest algorithm to remove outliers;
identifying, from the input data, a sequence of attributes for the well being drilled, wherein the sequence of attributes includes the input data measured at a sequence of depths in the well; and
predicting, in real time using machine learning on the sequence of attributes received while drilling the well, hydrocarbon show indicators classifying a presence of hydrocarbons at a pre-determined distance ahead of a drilling bit.

10. The non-transitory, computer-readable medium of claim 9, the operations further comprising scaling and normalizing the input data.

11. The non-transitory, computer-readable medium of claim 9, wherein the hydrocarbon show indicators include hydrocarbon wetness.

12. The non-transitory, computer-readable medium of claim 9, wherein predicting the hydrocarbon show indicators includes using a Haworth Wetness formula to determine, using mud gases logs, if oil is productive ahead of the drilling bit.

13. The non-transitory, computer-readable medium of claim 12, wherein predicting the hydrocarbon show indicators includes determining that Haworth Wetness formula yields a value within a specified range of 0.5 to 40%, indicating productive hydrocarbons.

14. The non-transitory, computer-readable medium of claim 9, wherein the sequence of attributes includes attributes for 100 feet of drilling.

15. The non-transitory, computer-readable medium of claim 9, wherein the pre-determined distance is 1000 feet ahead, in a downhole direction of the drilling bit.

16. The non-transitory, computer-readable medium of claim 9, wherein predicting hydrocarbon show indicators classifying the presence of hydrocarbons includes predicting a presence or absence of productive amounts of one or more of oil and natural gas.

17. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
receiving input data identifying, for different depths of a well that is being drilled, a drill bit location, a depth, a weight on bit, rotations per minute, a rate of penetration, lagged lithology percentages, and real-time mud gas logs;
performing data cleaning on the input data using an isolation forest algorithm to remove outliers;
identifying, from the input data, a sequence of attributes for the well being drilled, wherein the sequence of attributes includes the input data measured at a sequence of depths in the well; and
predicting, in real time using machine learning on the sequence of attributes received while drilling the well, hydrocarbon show indicators classifying a presence of hydrocarbons at a pre-determined distance ahead of a drilling bit.

18. The computer-implemented system of claim 17, the operations further comprising scaling and normalizing the input data.

19. The computer-implemented system of claim 17, wherein the hydrocarbon show indicators include hydrocarbon wetness.

20. The computer-implemented system of claim 17, wherein predicting the hydrocarbon show indicators includes using a Haworth Wetness formula to determine, using mud gases logs, if oil is productive ahead of the drilling bit.
